(19) United States
(12) Patent Application Publication
(10) Pub. No.: US 2013/0056054 A1
(43) Pub. Date: Mar. 7, 2013

(54) HIGH WORK FUNCTION LOW RESISTIVITY BACK CONTACT FOR THIN FILM SOLAR CELLS

(71) Applicant: Haifan Liang, Fremont, CA (US)

(72) Inventor: Haifan Liang, Fremont, CA (US)

(73) Assignee: INTERMOLECULAR, INC., San Jose, CA (US)

(21) Appl. No.: 13/226,181

(22) Filed: Sep. 6, 2011

(51) Int. Cl. H01L 31/0224

(52) U.S. Cl. 136/256

(57) ABSTRACT

Back contact materials and processes for use in the manufacturing of CdTe, CIGS, and CZTS TFPV superstrate solar cells are described. High conductivity, high work function materials of ReO₃ are used to form the ohmic contact to the absorber layers of the TFPV solar cells. The ReO₃ materials may be implemented alone or in combination with other high conductivity materials to for the back contact layer stack.

### FIELD OF THE INVENTION

The present invention relates generally to back contacts for thin film solar cells. More specifically, this invention relates to back contacts for copper indium gallium (sulfide) selenide (CIGS) solar cells, cadmium telluride (CdTe) solar cells, and copper zinc tin (sulfide) selenide (CZTS) solar cells.

### BACKGROUND OF THE INVENTION

Solar cells have been developed as clean, renewable energy sources to meet growing demand. Currently, crystalline silicon solar cells (both single crystal and polycrystalline) are the dominant technologies in the market. Crystalline silicon solar cells must use a thick substrate (>100 um) of silicon to absorb the sunlight since it has an indirect band gap. Also, the absorption coefficient is low for crystalline silicon because of the indirect band gap. The use of a thick substrate also means that the crystalline silicon solar cells must use high quality material to provide long minority carrier lifetimes to allow the carriers to diffuse to the junction. Therefore, crystalline silicon solar cell technologies lead to increased costs. Thin film solar cells based on amorphous silicon (a-Si), CIGS, CdTe, CZTS, etc. provide an opportunity to increase the material utilization since only thin films (<10 um) are generally required. CdTe and CZTS films have direct band gaps of about 1.5 eV and therefore, are efficient absorbers for wavelengths shorter than about 1100 nm. The absorption coefficient for CdTe is about 10⁵/cm and the absorption coefficient for CZTS is about 10⁴/cm. CIGS films have direct bandgaps in the range of 1.0 eV (CIS) to 1.65 eV (CGS) and are also efficient absorbers across the entire visible spectrum. The absorption coefficient for CIGS is about 10⁵/cm. Additionally, thin film solar cells can be fabricated at the module level, thus further decreasing the manufacturing costs. Furthermore, thin film solar cells may be fabricated on inexpensive substrates such as glass, plastics, and thin sheets of metal. Among the thin film solar cells, CIGS has demonstrated the best lab cell efficiency (above 20%) and the best large area module efficiency (>12%).

The increasing demand for environmentally friendly, sustainable and renewable energy sources is driving the development of large area, thin film photovoltaic (TFPV) devices. With a long-term goal of providing a significant percentage of global energy demand, there is a concomitant need for Earth-abundant, high conversion efficiency materials for use in photovoltaic devices. A number of Earth abundant direct-bandgap semiconductor materials now seem to show evidence of the potential for both high efficiency and low cost in Very Large Scale (VLS) production (e.g. greater than 100 gigawatt (GW)), yet relatively little attention has been devoted to their development and characterization.

Among the TFPV technologies, CIGS and CdTe are the two that have reached volume production with greater than 10% stabilized module efficiencies. Solar cell production volume must increase tremendously in the coming decades to meet sharply growing energy needs. However, the supply of In, Ga and Te may inhibit annual production of CIGS and CdTe solar panels. Moreover, price increases and supply constraints in In and Ga could result from the aggregate demand for these materials used in flat panel displays (FPD) and light-emitting diodes (LED) along with CIGS TFPV. Also, there are concerns about the toxicity of Cd throughout the lifecycle of the CdTe TFPV solar modules. Efforts to develop devices that leverage manufacturing and R&D infrastructure related to TFPV using more widely available and more environmentally friendly raw materials should be considered a top priority for research.

The immaturity of TFPV devices exploiting Earth abundant materials represents a daunting challenge in terms of the time-to-commercialization. That same immaturity also suggests an enticing opportunity for breakthrough discoveries. A multicomponent system such as CdTe, CIGS, or CZTS requires management of multiple kinetic pathways, thermodynamic phase equilibrium considerations, defect chemistries, and interfacial control. The vast phase-space to be managed includes process parameters, source material choices, compositions, and overall integration schemes. Traditional R&D methods are ill-equipped to address such complexity, and the traditionally slow pace of R&D could limit any new material from reaching industrial relevance when having to compete with the incrementally improving performance of already established TFPV fabrication lines.

However, due to the complexity of the material, cell structure and manufacturing process, both the fundamental scientific understanding and large scale manufacturability are yet to be improved for CIGS and CZTS solar cells. As the photovoltaic industry pushes to achieve grid parity, much faster and broader investigation is needed to explore the material, device, and process windows for higher efficiency and a lower cost of manufacturing process. Efficient methods for forming different types of CIGS and CZTS solar cells that can be evaluated are necessary.

The manufacture of TFPV modules entails the integration and sequencing of many unit processing steps. As an example, TFPV manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

The back contact structure for TFPV solar cells must meet a number of requirements such as high conductivity, good ohmic contact to the absorber layer, good ohmic contact to the TCO layer for monolithic integration, good adhesion to the substrate, good adhesion to the tabs, ease of scribing, thermo-mechanically stable during manufacturing and during deployment in the field, low cost, high deposition rate, a coefficient of thermal expansion similar to the substrate and other materials in the TFPV solar cell stack, high reflectance, electromigration resistance, etc. It is difficult to develop a single material that will meet all of these requirements. For example, p-type CdTe has a band gap of about 1.45 eV and an electron affinity of about 4.5 eV. Therefore, a good ohmic contact can only be formed using materials with a work function greater than about 5.9 eV. Most metals have work functions that are less than 5.9 eV. To date, most back contacts for CdTe have used a variety of heavily-doped Cu alloys to attempt to overcome the low work function (˜4.7 eV) of pure Cu. The mis-match in work functions between the contact and the absorber layer leads to a barrier at the interface that impedes the transport of carriers. This negatively impacts the performance of the solar cell.

Therefore, there is a need to develop back contact material stacks that address each of the requirements listed above to improve the efficiency of TFPV solar cells. In addition to meeting the required materials properties, the back contact material stacks must also meet the requirement of ease of manufacturing.

### SUMMARY OF THE INVENTION

In some embodiments of the present invention, back contact material stacks are formed to address the requirements listed above. High conductivity materials are used as primary current transport layers. High work function interface layers are used to ensure good ohmic contact between the back contact material stack and the absorber layer.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram of a simple CdTe superstrate TFPV stack according to an embodiment described herein.

FIG. 2 illustrates a schematic diagram of a simple CIGS superstrate TFPV stack according to an embodiment described herein.

FIG. 3 illustrates a schematic diagram of a simple CZTS superstrate TFPV stack according to an embodiment described herein.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

As used herein, “CIGS” will be understood to represent the entire range of related alloys denoted by Cu(InₓGa₁₋ₓ)(S_{y}Se_{2-y}) where 0≦x≦1 and 0≦y≦2. As used herein, “CZTS” will be understood to represent the entire range of related alloys denoted by Cu₂ZnSn(S_{y}Se_{1-y})₄ where 0≦y≦1.

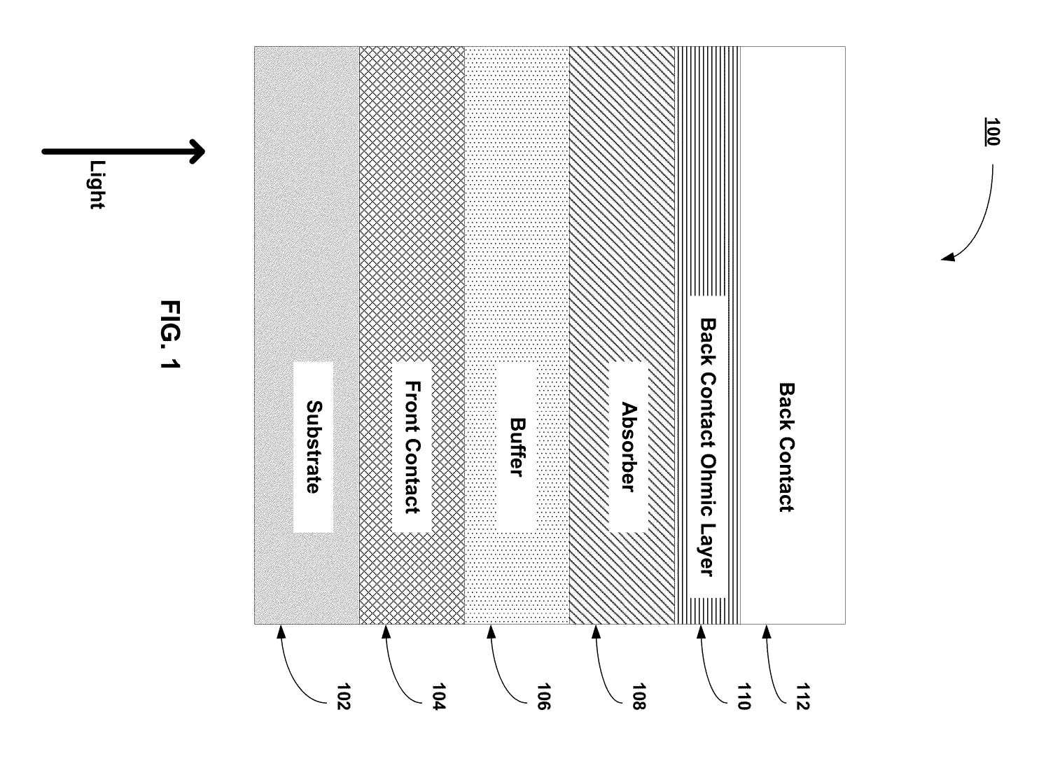

In FIGS. 1-3 below, a TFPV material stack is illustrated using a simple planar structure. Those skilled in the art will appreciate that the description and teachings to follow can be readily applied to any simple or complex TFPV solar cell morphology. The drawings are not to scale and are for illustrative purposes only and do not limit the application of the present invention.

FIG. 1 illustrates a schematic diagram of a simple CdTe superstrate TFPV stack according to an embodiment described herein. A front contact layer, 104, is formed on a substrate, 102. Typically, suitable substrates comprise soda lime glass (SLG) or a clear polymer. The light is incident on the TFPV solar cell through the substrate. Examples of suitable front contact materials comprise indium tin oxide (ITO), fluorine doped tin oxide (SnO:F), aluminum doped zirconium oxide (ZrO:Al), etc. These materials are conductive and are also substantially transparent to light in the visible spectrum. Typically, reactive physical vapor deposition (PVD) is the preferred method of deposition for the front contact layer. The thickness of the front contact layer is typically between about 500 nm and about 800 nm. The properties and deposition technologies for the front contact layer are well developed.

An n-type buffer layer, 106, is then deposited on top of the front contact layer. Examples of suitable n-type buffer layers comprise CdS, ZnS, CdZnS, etc. CdS is the material most often used as the n-type buffer layer in CdTe TFPV solar cells. The buffer layer may be deposited using chemical bath deposition (CBD), PVD, or evaporation. The thickness of the buffer layer is typically about 50 nm. The performance of the buffer layer is sensitive to materials properties such as crystallinity, grain size, surface roughness, composition, defect concentration, etc. as well as processing parameters such as temperature, deposition rate, thermal treatments, etc.

A p-type absorber layer, 108, of CdTe is then deposited on top of the buffer layer. The absorber layer may be formed using a variety of techniques such as PVD, co-evaporation, printing or spraying of inks, chemical vapor deposition (CVD), etc. Typically, PVD is the preferred method of deposition for the CdTe layer. The thickness of the CdTe layer is typically between about 2.0 um and about 4.0 um. The performance of the CdTe layer is sensitive to materials properties such as crystallinity, grain size, surface roughness, composition, defect concentration, etc. as well as processing parameters such as temperature, deposition rate, thermal treatments, etc.

Traditionally, the back contact for CdTe TFPV solar cells may be formed from several layers. As illustrated in FIG. 1, a back contact ohmic layer, 110, is formed on top of the CdTe absorber layer. The back contact ohmic layer is typically a semiconducting material with a very high work function. Examples of suitable back contact ohmic layer materials comprise ZnTe:Cu, Cu₂Te, HgTe, As₂Te₃, etc. These materials are p-type. Typically, PVD is the preferred method of deposition for the back contact interface layer. The thickness of the back contact ohmic layer is typically between about 300 nm and about 500 nm. The performance of the back contact interface layer is sensitive to materials properties such as crystallinity, grain size, surface roughness, composition, defect concentration, etc. as well as processing parameters such as temperature, deposition rate, thermal treatments, etc.

A second layer, 112, of the back contact is formed on top of the back contact ohmic layer and serves as the primary current transport layer. Examples of suitable back contact layer materials comprise ITO, metals, etc. These materials are n-type. Typically, PVD is the preferred method of deposition for the back contact layer. The thickness of the back contact layer is typically about 500 nm.

In some embodiments of the present invention, an alternative back contact structure is disclosed for use in TFPV CdTe solar cells. ReO₃ is a high conductivity material (resistivity ˜1×10⁻⁶ Ωcm) with a high work function (>˜6.0 eV). Therefore, ReO₃ is a good candidate for use as a back contact ohmic layer, 110, to CdTe absorber layers. Other beneficial attributes of ReO₃ include high chemical stability in water, aqueous acid solutions, and aqueous alkali solutions. The high conductivity of the ReO₃ layer improves the performance of the solar cell relative to the performance of a solar cell using a semiconductor back contact ohmic layer. The ReO₃ may be formed using any well known deposition technology such as reactive-PVD, reactive-evaporation, CVD, etc. In some embodiments of the present invention, the ReO₃ layer is used as the entire back contact layer for a CdTe TFPV solar cell (layers 110 and 112) (i.e. a single layer). In some embodiments of the present invention, the ReO₃ layer is used in combination with other layers to form the back contact layer stack for a CdTe TFPV solar cell. In these embodiments, the ReO₃ is used as the back contact ohmic layer, 110, and a less expensive, high conductivity layer is used as the bulk current transport layer, 112. In the case where the ReO₃ is used as the back contact ohmic layer, the thickness of the ReO₃ would be about 10 nm and the remainder of the back contact material would be comprised of the less expensive, high conductivity layer.

In some embodiments of the present invention, an alternative back contact structure is disclosed for use in TFPV CdTe solar cells. ReNₓ (where the atomic ratio of N:Re is between about 0.2 and about 1.3) is a high conductivity material (resistivity ˜250×10⁻⁶ Ωcm). Therefore, ReNₓ may be a good candidate for use as a back contact interface layer, 110, to CdTe absorber layers. The high conductivity of the ReNₓ layer improves the performance of the solar cell relative to the performance of a solar cell using a semiconductor back contact ohmic layer. The ReNₓ may be formed using any well known deposition technology such as reactive-PVD, reactive-evaporation, CVD, etc. In some embodiments of the present invention, the ReNₓ layer is used as the entire back contact layer for a CdTe TFPV solar cell (layers 110 and 112) (i.e. a single layer). In some embodiments of the present invention, the ReNₓ layer is used in combination with other layers to form the back contact layer stack for a CdTe TFPV solar cell. In these embodiments, the ReNₓ is used as the back contact interface layer, 110, and a less expensive, high conductivity layer is used as the bulk current transport layer, 112. In the case where the ReNₓ is used as the back contact ohmic layer, the thickness of the ReNₓ would be about 10 nm and the remainder of the back contact material would be comprised of the less expensive, high conductivity layer.

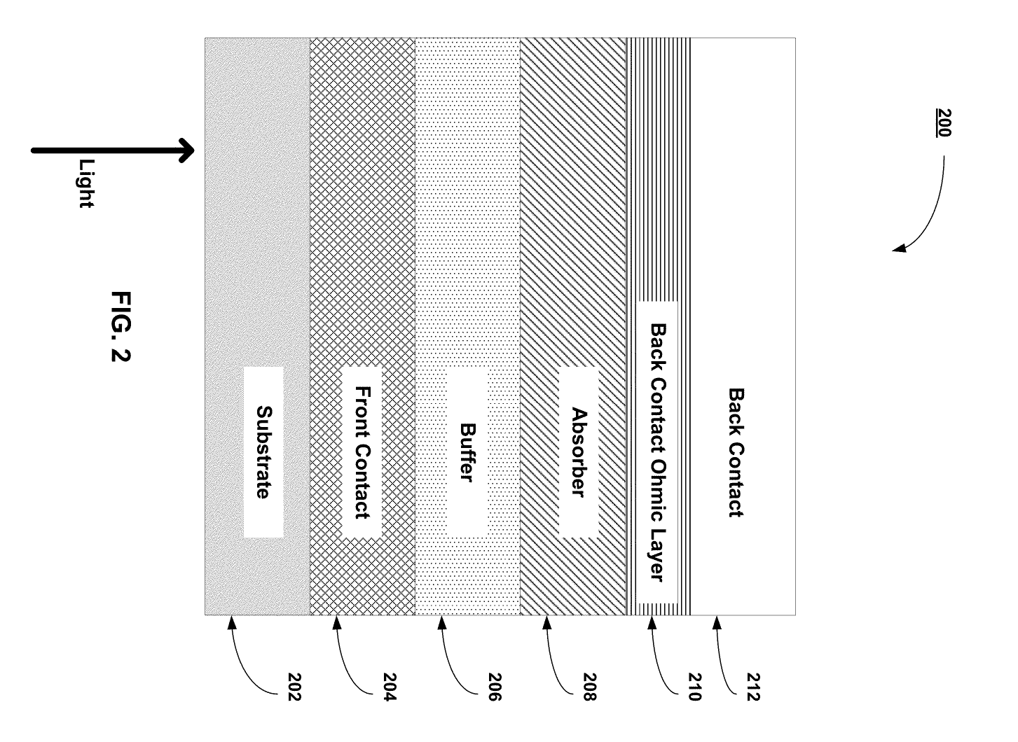

FIG. 2 illustrates a schematic diagram of a simple CIGS superstrate TFPV stack according to an embodiment described herein. A front contact layer, 204, is formed on a substrate, 202. Typically, suitable substrates comprise soda lime glass (SLG) or a clear polymer. The light is incident on the TFPV solar cell through the substrate. Examples of suitable front contact materials comprise indium tin oxide (ITO), fluorine doped tin oxide (SnO:F), aluminum doped zinc oxide (ZnO:Al), etc. These materials are conductive and are also substantially transparent to light in the visible spectrum. Typically, reactive PVD is the preferred method of deposition for the front contact layer. The thickness of the front contact layer is typically between about 500 nm and about 800 nm. The properties and deposition technologies for the front contact layer are well developed.

An n-type buffer layer, 206, is then deposited on top of the front contact layer. Examples of suitable n-type buffer layers comprise CdS, ZnS, CdZnS, etc. CdS is the material most often used as the n-type buffer layer in CIGS TFPV solar cells. The buffer layer may be deposited using chemical bath deposition (CBD), PVD, or evaporation. The thickness of the buffer layer is typically about 50 nm. The performance of the buffer layer is sensitive to materials properties such as crystallinity, grain size, surface roughness, composition, defect concentration, etc. as well as processing parameters such as temperature, deposition rate, thermal treatments, etc.

A p-type absorber layer, 208, of CIGS is then deposited on top of the buffer layer. The absorber layer may be formed using a variety of techniques such as PVD, co-evaporation, printing or spraying of inks, CVD, etc. Typically, PVD is the preferred method of deposition for the CIGS layer. The thickness of the CIGS layer is typically between about 1.0 um and about 2.0 um. The performance of the CIGS layer is sensitive to materials properties such as crystallinity, grain size, surface roughness, composition, defect concentration, etc. as well as processing parameters such as temperature, deposition rate, thermal treatments, etc.

An optional MoSe₂ layer, (not shown), can be formed on the absorber layer. The MoSe₂ layer forms an ohmic contact to the absorber layer. The thickness of the MoSe₂ layer is typically between about 10 nm and about 20 nm.

A back contact layer, 212, is formed on top of the CIGS layer or the MoSe₂ layer if present. An example of a suitable back contact layer material is Mo. The back contact may comprise a single layer or may be formed from multiple layers. In FIG. 2, only a single layer is illustrated. Typically, PVD is the preferred method of deposition for the back contact layer. The thickness of the back contact layer is typically between about 0.3 um and about 0.5 um. The properties and deposition technologies for the back contact layer are well developed.

In some embodiments of the present invention, an alternative back contact structure is disclosed for use in TFPV CIGS solar cells. ReO₃ is a high conductivity material (resistivity ˜1×10⁻⁶ Ωcm) with a high work function (>˜6.0 eV). Therefore, ReO₃ is a good candidate for use as a back contact layer, 212, to CIGS absorber layers. Other beneficial attributes of ReO₃ include high chemical stability in water, aqueous acid solutions, and aqueous alkali solutions. The high conductivity of the ReO₃ layer improves the performance of the solar cell relative to the performance of a solar cell using a semiconductor back contact ohmic layer. The ReO₃ may be formed using any well known deposition technology such as reactive-PVD, reactive-evaporation, CVD, etc. In some embodiments of the present invention, the ReO₃ layer is used as the entire back contact layer for a CIGS TFPV solar cell. In some embodiments of the present invention, the ReO₃ layer is used in combination with other layers to form the back contact layer stack for a CIGS TFPV solar cell. In these embodiments, the ReO₃ is used as an ohmic contact interface layer and a less expensive, high conductivity layer is used as a bulk current transport layer (not shown). In the case where the ReO₃ is used as the back contact ohmic layer, the thickness of the ReO₃ would be about 10 nm and the remainder of the back contact material would be comprised of the less expensive, high conductivity layer.

In some embodiments of the present invention, an alternative back contact structure is disclosed for use in TFPV CIGS solar cells. ReNₓ (where the atomic ratio of N:Re is between about 0.2 and about 1.3) is a high conductivity material (resistivity ˜250×10⁻⁶ Ωcm). Therefore, ReNₓ may be a good candidate for use as a back contact layer, 212, to CIGS absorber layers. The high conductivity of the ReNₓ layer improves the performance of the solar cell relative to the performance of a solar cell using a semiconductor back contact ohmic layer. The ReNₓ may be formed using any well known deposition technology such as reactive-PVD, reactive-evaporation, CVD, etc. In some embodiments of the present invention, the ReNₓ layer is used as the entire back contact layer for a CIGS TFPV solar cell. In some embodiments of the present invention, the ReNₓ layer is used in combination with other layers to form the back contact layer stack for a CIGS TFPV solar cell. In these embodiments, the ReNₓ is used as an ohmic back contact interface layer and a less expensive, high conductivity layer is used as the bulk current transport layer (not shown). In the case where the ReNₓ is used as the back contact ohmic layer, the thickness of the ReNₓ would be about 10 nm and the remainder of the back contact material would be comprised of the less expensive, high conductivity layer.

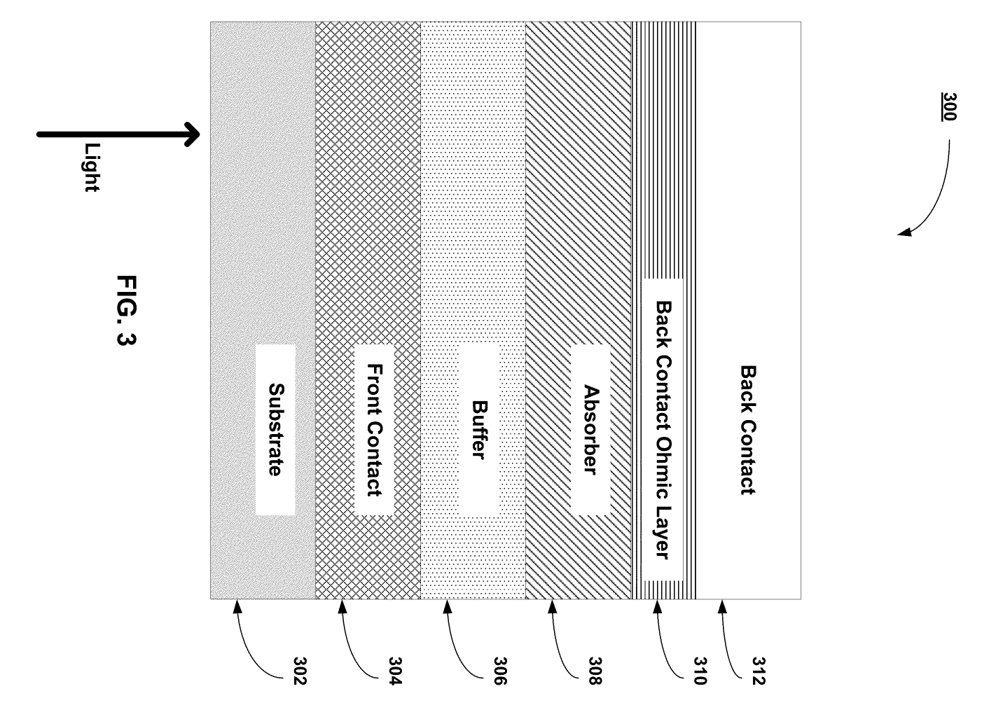

FIG. 3 illustrates a schematic diagram of a simple CZTS superstrate TFPV stack according to an embodiment described herein. A front contact layer, 304, is formed on a substrate, 302. Typically, suitable substrates comprise soda lime glass (SLG) or a clear polymer. The light is incident on the TFPV solar cell through the substrate. Examples of suitable front contact materials comprise indium tin oxide (ITO), fluorine doped tin oxide (SnO:F), aluminum doped zinc oxide (ZnO:Al), etc. These materials are conductive and are also substantially transparent to light in the visible spectrum. Typically, reactive PVD is the preferred method of deposition for the front contact layer. The thickness of the front contact layer is typically between about 500 nm and about 800 nm. The properties and deposition technologies for the front contact layer are well developed.

An n-type buffer layer, 306, is then deposited on top of the front contact layer. Examples of suitable n-type buffer layers comprise CdS, ZnS, CdZnS, etc. CdS is the material most often used as the n-type buffer layer in CZTS TFPV solar cells. The buffer layer may be deposited using chemical bath deposition (CBD), PVD, or evaporation. The thickness of the buffer layer is typically about 50 nm. The performance of the buffer layer is sensitive to materials properties such as crystallinity, grain size, surface roughness, composition, defect concentration, etc. as well as processing parameters such as temperature, deposition rate, thermal treatments, etc.

A p-type absorber layer, 308, of CZTS is then deposited on top of the buffer layer. The absorber layer may be formed using a variety of techniques such as PVD, co-evaporation, printing or spraying of inks, CVD, etc. Typically, PVD is the preferred method of deposition for the CZTS layer. The thickness of the CZTS layer is typically between about 1.0 um and about 2.0 um. The performance of the CZTS layer is sensitive to materials properties such as crystallinity, grain size, surface roughness, composition, defect concentration, etc. as well as processing parameters such as temperature, deposition rate, thermal treatments, etc.

An optional MoSe₂ layer, (not shown), can be formed on the absorber layer. The MoSe₂ layer forms an ohmic contact to the absorber layer. The thickness of the MoSe₂ layer is typically between about 10 nm and about 20 nm.

A back contact layer, 312, is formed on top of the CZTS layer or the MoSe₂ layer if present. The back contact may comprise a single layer or may be formed from multiple layers. An example of a suitable back contact layer material is Mo. In FIG. 3, only a single layer is illustrated. Typically, PVD is the preferred method of deposition for the back contact layer. The thickness of the back contact layer is typically between about 0.3 um and about 0.5 um.

In some embodiments of the present invention, an alternative back contact structure is disclosed for use in TFPV CZTS solar cells. ReO₃ is a high conductivity material (resistivity ˜1×10⁻⁶ Ωcm) with a high work function (>˜6.0 eV). Therefore, ReO₃ is a good candidate for use as a back contact layer, 312, to CZTS absorber layers. Other beneficial attributes of ReO₃ include high chemical stability in water, aqueous acid solutions, and aqueous alkali solutions. The high conductivity of the ReO₃ layer improves the performance of the solar cell relative to the performance of a solar cell using a semiconductor back contact ohmic layer. The ReO₃ may be formed using any well known deposition technology such as reactive-PVD, reactive-evaporation, CVD, etc. In some embodiments of the present invention, the ReO₃ layer is used as the entire back contact layer, 312, for a CZTS TFPV solar cell. In some embodiments of the present invention, the ReO₃ layer is used in combination with other layers to form the back contact layer stack for a CZTS TFPV solar cell. In these embodiments, the ReO₃ is used as an ohmic contact interface layer and a less expensive, high conductivity layer is used as the bulk current transport layer (not shown). In the case where the ReO₃ is used as the back contact ohmic layer, the thickness of the ReO₃ would be about 10 nm and the remainder of the back contact material would be comprised of the less expensive, high conductivity layer.

In some embodiments of the present invention, an alternative back contact structure is disclosed for use in TFPV CZTS solar cells. ReNₓ (where the atomic ratio of N:Re is between about 0.2 and about 1.3) is a high conductivity material (resistivity ˜250×10⁻⁶ Ωcm). Therefore, ReNₓ may be a good candidate for use as a back contact layer, 312, to CZTS absorber layers. The high conductivity of the ReNₓ layer improves the performance of the solar cell relative to the performance of a solar cell using a semiconductor back contact ohmic layer. The ReNₓ may be formed using any well known deposition technology such as reactive-PVD, reactive-evaporation, CVD, etc. In some embodiments of the present invention, the ReNₓ layer is used as the entire back contact layer for a CZTS TFPV solar cell. In some embodiments of the present invention, the ReNₓ layer is used in combination with other layers to form the back contact layer stack for a CZTS TFPV solar cell. In these embodiments, the ReNₓ is used as an ohmic back contact interface layer and a less expensive, high conductivity layer is used as the bulk current transport layer (not shown). In the case where the ReNₓ is used as the back contact ohmic layer, the thickness of the ReNₓ would be about 10 nm and the remainder of the back contact material would be comprised of the less expensive, high conductivity layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A back contact layer stack for use in a superstrate CdTe thin film photovoltaic solar cell comprising:
a layer of a rhenium containing material in contact with a CdTe absorber layer.

2. The back contact layer stack of claim 1 wherein the rhenium containing material is one of ReO₃ or ReNₓ where the ratio of Re:N is between about 0.2 and about 1.3.

3. The back contact layer stack of claim 1 wherein the rhenium containing material is deposited using one of reactive-PVD, reactive-evaporation or CVD.

4. The back contact layer stack of claim 1 further comprising one or more conductive materials in contact with the rhenium containing material.

5. A back contact layer stack for use in a superstrate CIGS thin film photovoltaic solar cell comprising:
a layer of a rhenium containing material in contact with a CIGS absorber layer.

6. The back contact layer stack of claim 5 wherein the rhenium containing material is one of ReO₃ or ReNₓ where the ratio of Re:N is between about 0.2 and about 1.3.

7. The back contact layer stack of claim 5 wherein the rhenium containing material is deposited using one of reactive-PVD, reactive-evaporation or CVD.

8. The back contact layer stack of claim 5 further comprising one or more conductive materials in contact with the rhenium containing material.

9. A back contact layer stack for use in a superstrate CZTS thin film photovoltaic solar cell comprising:
a layer of a rhenium containing material in contact with a CZTS absorber layer.

10. The back contact layer stack of claim 9 wherein the rhenium containing material is one of ReO₃ or ReNₓ where the ratio of Re:N is between about 0.2 and about 1.3.

11. The back contact layer stack of claim 9 wherein the rhenium containing material is deposited using one of reactive-PVD, reactive-evaporation or CVD.

12. The back contact layer stack of claim 9 further comprising one or more conductive materials in contact with the rhenium containing material.
